(19) United States
(12) Patent Application Publication
(10) Pub. No.: US 2008/0169574 A1
(43) Pub. Date: Jul. 17, 2008

(54) Direct Die Attachment

(75) Inventors: Petri Molkkari, Tampere (FI); Pauliina Mansikkamaki, Hameenkyro (FI); Matti Mantysalo, Tampere (FI); Jani Miettinen, Hyvinkaa (FI); Jani Valtanen, Tampere (FI)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Nokia Corporation, Espoo (FI)

(21) Appl. No.: 11/622,760

(22) Filed: Jan. 12, 2007

(51) Int. Cl. H01L 23/48; H01L 21/00

(52) U.S. Cl. 257/782; 438/119; 257/E21.001; 257/E23.01

(57) ABSTRACT

A method is presented for bare die attachment using conductive ink dots. Dielectric ink dots may be applied, for example as spacer bumps or for attaching. The conductive ink dots are not cured until die and substrate are placed on top of each other, and then cured to form a conductive connection between die and substrate.

### FIELD OF THE INVENTION

The current invention relates to the connection or attachment of semiconductor dies on a substrate or further dies, and in particular to the direct attachment of dies without using conventional solder bumps or bonding wires.

### RELATED ART

Integrated circuits and semiconductor devices are used in many areas and products. Basically, miniaturized electronic circuits and connection elements are provided on a semiconductor wafer, which is then divided into a plurality of single dies or chips.

In approaches like System-in-Package (SiP), several dies are combined in a single package to provide all functions of a complete system or module within a single package. Also, dies of different material and/or production technologies may be combined in one package. Thus, overall size and cost of a device may be considerably reduced, while providing all functions with only one module. For example, a memory die may be combined with a controller and a signal filter in one package. Various dies are mounted on a substrate or leadframe, either in horizontal (next to each other) or vertical (on top of each other) arrangement. The substrate may be made from any suitable material, such as a semiconductor (e.g. silicon), polymer, or ceramic. To protect the dies from any external influences, the substrate with mounted dies is then typically packaged by adding a non-conductive material around the components. Materials commonly used for this encapsulation are, for example, epoxy, polymer, or ceramic.

Besides the semiconductor dies with integrated circuits (ICs), a System-in-Package (SiP) may also comprise further components, such as passive components as separate units or patterned into the substrate, filters (e.g. SAW, surface acoustic wave, filters), electromagnetic shielding elements, mechanical parts, connectors, and other components as known in the art.

The required electrical connection between a die and the substrate (or between several dies) is obtained using fine wires. Another approach is known as flip-chip structure or direct attach. In this type of die attachment, solder bumps or beads are deposited on the substrate surface by stencil printing or pin transfer. The die to be attached on the substrate surface is then turned with its functional surface upside down (hence the term “flip chip”) and connected to the substrate by reflowing the solder.

### SUMMARY

A method according to the invention is presented that comprises in exemplary embodiments: non-contact depositing of at least one dot of a conductive ink onto a first surface of a first carrier; arranging said first carrier and a second carrier on top of each other, wherein said first surface of said first carrier and a first surface of said second carrier are facing each other; and curing said at least one dot of conductive ink to achieve a conductive attachment between said carrier surfaces. Thus, the curing of the conductive ink printed on the surface(s) may provide a connection between both carriers, while no bumps or wires beside the deposited ink dots are needed. Also, no direct contact is made with the carrier surfaces during the depositing process.

In some embodiments, said depositing of ink onto said surface may comprise jet-printing of said ink. This allows for a fast and cost-efficient production cycle for die attachment, as only a printing step and a curing step are necessary as a basis. The jet-printing of ink may for example be achieved by inducing mechanical pressure waves in an ink reservoir having an aperture. Such pressure waves may in exemplary embodiments be generated by a piezo-electric element. A piezo element may be easily controlled to vary drop size, and e.g. different waveforms may be used to control the jet-printing process

The method may in some embodiments further comprise non-contact depositing of at least one dot of a dielectric ink onto at least one of said first surface of said first carrier and said first surface of said second carrier. Dielectric dots may for example be utilized as spacer bumps and/or for stronger connection of the carriers.

The method may in some embodiments comprise curing said at least one printed dielectric ink dot before arranging said carriers on top of each other. In this way, some or all of the dielectric dots are hardened and may serve as spacers for the carrier that is placed on top of the surface.

Curing is in exemplary embodiments achieved by heating at least a part of said ink dots (dielectric and/or conductive dots) on said carrier surfaces.

In some embodiments, the method may further comprise depositing at least one further layer of ink on top of deposited ink dots. In this way, desired bump profiles and shapes or specific functional properties of the dots may be formed.

In further embodiments, it may include depositing at least one further layer of ink on top of at least one of said cured ink dots, and curing said at least one further layer of ink.

A plurality of ink dots may be deposited in exemplary embodiments, and said volumes may be deposited in a predetermined pattern. A pattern may be adapted to the necessary number and locations of electrical connections, and also e.g. to the desired effect of the dielectric bumps as spacers, protection elements or connection elements. In further embodiments, a plurality of said dots may be deposited in a pattern which includes a number of said dielectric ink dots surrounded by a number of said conductive ink dots.

In exemplary implementations, said conductive ink dots are deposited on a metallized area of said carrier.

At least one of said first and second carriers may include a semiconductor die in some embodiments.

Furthermore, at least one of said first and second carriers may include a die substrate. Such a substrate may comprise e.g. a polymer material, a ceramic material, or a semiconductor material.

A device is further presented according to a further aspect of the invention, comprising at least a first and a second carrier arranged on top of each other; structures comprising at least one cured conductive ink dot between surfaces of said carriers; wherein said cured conductive ink dots are fixedly and directly connected to both said carrier surfaces.

The ink dots may for example comprise nano-particles of a conductive material.

The device may in further embodiments comprise structures comprising at least one cured dielectric ink dot between said surfaces of said carriers, wherein said cured dielectric ink dots are fixedly and directly connected to at least one of said carrier surfaces.

At least one of the carriers may, in exemplary embodiments, be a semiconductor die. This allows a flip-chip type connection of semiconductor dies to a substrate or other dies without using wires or soldering.

At least one of the carriers may be a die substrate in some embodiments. Such a substrate may for example comprise a polymer material, a ceramic material, or a semiconductor material.

Also presented is an apparatus which may comprise a jet printing head connected to at least one reservoir for depositing conductive and/or dielectric ink on a carrier; an actuator for arranging two printed carriers on top of each other with their printed surfaces facing each other; and a heating element for curing said deposited conductive and/or dielectric ink.

Furthermore, an apparatus is provided that may comprise means for non-contact depositing of at least one dot of a conductive ink onto a first surface of a first carrier; means for placing said first carrier and a second carrier on top of each other, wherein said first surface of said first carrier and a first surface of said second carrier are arranged facing each other; and means for curing said at least one dot of conductive ink to achieve a conductive attachment between said carrier surfaces.

### BRIEF DESCRIPTION OF FIGURES

In the following, exemplary embodiments of the invention will be explained in more detail with reference to the appended figures, wherein

FIG. 1a shows a top view and side view of both die and substrate in an exemplary embodiment;

FIG. 1b shows the arrangement of die and substrate of FIG. 1 attached together;

FIG. 2a shows another exemplary arrangement of ink dots on die and substrate;

FIG. 2b shows the arrangement of die and substrate of FIG. 3 attached together; and

FIG. 3 illustrates exemplary method steps of an embodiment of the invention.

### DETAILED DESCRIPTION OF EXEMPLARY EMBODIMENTS

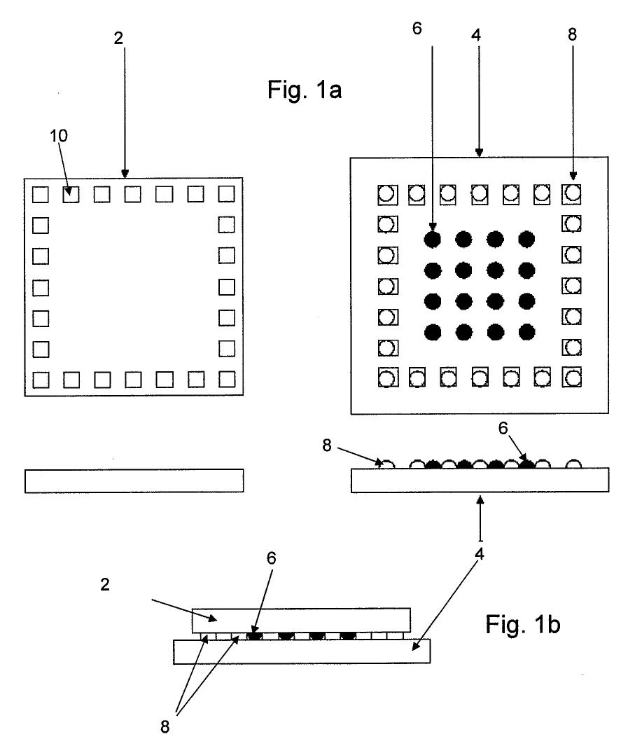

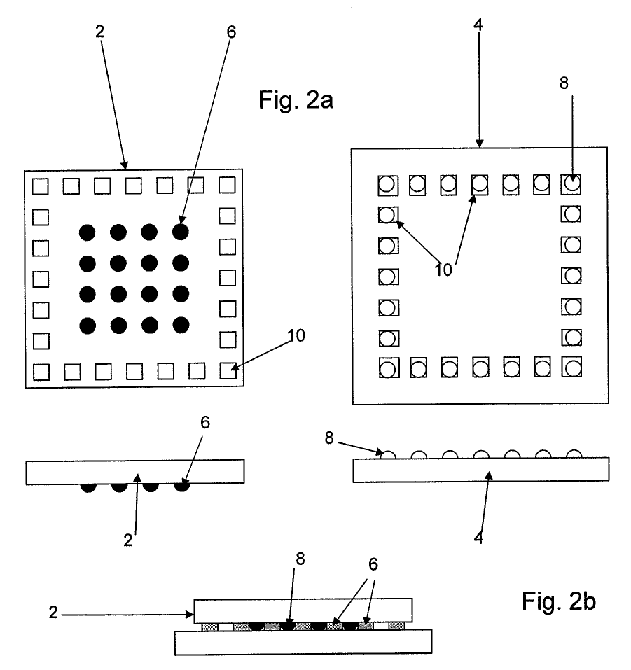

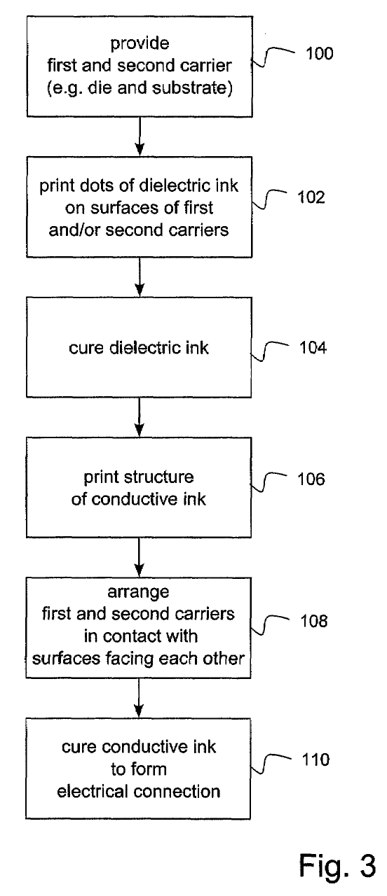

Steps of an exemplary method according to the invention are illustrated in FIG. 3. Structural elements are depicted in the top and side views of FIGS. 1 and 2, showing die and substrate before attachment in FIG. 1a and FIG. 2a, respectively, and a cross section of an attached die and substrate in FIG. 1b and FIG. 2b, respectively.

Two carriers 2 and 4 may be provided (step 100 of FIG. 3) which should be conductively attached. In an exemplary embodiment, such carriers may be a die 2 and a substrate 4, as shown in FIGS. 1 and 2. The substrate 4 may be made of any material, for example a polymer, a semiconductor such as silicon or a ceramic. The die 2 may e.g. be a semiconductor die provided with integrated circuits and/or other functional electronic elements.

In a first depositing step 102, a functional (first) surface of the substrate 4 may be provided with dots 6 of dielectric ink, shown in FIG. 1a. The term “ink” in this context is not limited to conventional ink that is known from various printing applications, but rather refers to any fluid material that can be applied to a surface in a non-contact manner, such as jet-printing, and cured subsequently. This includes liquid solutions of conductive nano-particles (e.g. silver or copper particles) for a conductive ink, as well as thermosetting conductive and non-conductive polymers or resins, and many more. Several dots or bumps 6, 8 may be placed in any arbitrary pattern and distance as desired, by moving the carriers 2, 4 or the printer head.

Curing of the printed dielectric dots 6 may be performed in some embodiments, as indicated by optional step 104 of FIG. 3; alternatively, the dielectric dots 6 may be left uncured. A decision of whether dielectric dots 6 are cured or not may be dependent of characteristics of the substrate 4, die 2 and used inks. The curing procedure is discussed in more detail below.

A non-contact deposition of dots and structures 6, 8 of ink on carriers 2, 4 may be performed in several ways. In exemplary embodiments, a printing device similar to an ink-jet printer may be used to obtain small dots placed at selected positions. In particular embodiments, this may be a demand-mode jet printer, that is, a printer that ejects a defined quantity of ink (only) when desired. Such a jet printer may utilize a reservoir filled with an essentially liquid printing ink, having an aperture to eject droplets of ink. A droplet may be produced by mechanically inducing pressure waves into the ink reservoir. For example, a piezo-electric element may be included which induces pressure waves in the reservoir, the piezo-electric element being driven by a defined and controllable operating voltage.

Afterwards, conductive dots 8 may be added in a further printing process in step 106 (see FIG. 3), now using a conductive ink for printing. The general printing procedure may be performed in a way similar to the application of dielectric ink dots 6. Conductive dots may optionally be placed on predefined landing areas 10 such as metallized pads, in order to ensure a functional electronic contact and good adhesion between die and substrate. Such pads 10 may be previously provided on a substrate and/or die and may be produced during wafer manufacturing. The conductive dots 8 may be placed on the die or the substrate, as desired. In the examples of FIG. 1 and 2, they are provided on pads 10 of the substrate 4; however, they could also be placed directly on a die 2 in further embodiments.

When all necessary bumps or dots 6, 8, i.e. any structures to be applied by printing, have been placed, the die 2 is arranged on top of the printed substrate 4 or vice versa in step 108. Printed surfaces (or functional/connection surfaces in general) are oriented facing each other. If, in a particular embodiment, both surfaces of a die 2 or substrate 4 are printed (not shown), e.g. when another die is intended to be placed on top of a first one in a die stacking manner, this further die may be placed on top of the first one before arranging these on a substrate, or the other way round.

It should be noted that the conductive ink 8 is not cured before arranging die 2 and substrate 4 on top of each other. In some embodiments, the dielectric ink dots 6 have not been previously cured either, while in other embodiments some or all dielectric dots 6 may be cured (or may be absent).

Subsequent curing of the conductive ink dots 8 in step 110 then provides a direct electrical connection of the respective substrate/die surfaces 4, 2 and also a secure attachment of the die 2 to the substrate 4. If the dielectric ink 6 has not been cured until die 2 and substrate 4 are arranged together, an even stronger attachment due to the bonding of dielectric ink dots 6 to both surfaces may be achieved. Also, only a part of the dielectric printed dots 6 may be cured in some embodiments to act as spacer elements between the contact surfaces, while others are not cured and thus contribute to a secure fixation of both elements after curing is completed.

Curing of the dots, both dielectric 6 and conductive 8 ink dots, may be performed in several ways. Naturally, the curing procedure will be dependent on the specific type of ink used for printing and its constituents. For example, an ink may include solvents, metallic (or other conductive) nano-particles, filler materials, polymer material, surfactants, or detergents, as well as other ingredients. Temperature and pressure as well as the type of atmosphere present (e.g. air or nitrogen) may have an influence on the ink properties and may thus be used to control a curing procedure. In some embodiments, the printed carrier or only a part of a carrier may be exposed to heat to volatilize solvents, or to set a thermosetting polymer. Surface characteristics of the carrier (2, 4) surfaces also may have an effect on the curing procedure and e.g. on shapes and sizes of the finalized printed dots and structures after curing. Curing time and process may be similarly dependent on such parameters, but also on printed dot size, since e.g. solvent in a dot with smaller surface will take less time to vaporize.

To obtain a certain dot or bump geometry and shape, several layers of (either conductive or non-conductive) ink and also layers of different types of inks may be applied on top of each other, in order to obtain specific characteristics of these structures (e.g. hard spacer bumps, soft connection dots which are less sensitive to strain). An underlying layer may be cured before the next layer is applied, or left uncured if ink properties are suitable.

Any combinations of printed substrate and printed die are possible. For example, both dielectric 6 and conductive 8 printed dots/structures may be applied on the die surface 2, and the substrate 4 is not printed at all. This is shown in FIGS. 1a and 1b. In another example embodiment, only dielectric dots 6 may be printed on one of the elements (i.e. on die or substrate) while conductive dots 8 are printed on the other one. In FIGS. 2a and 2b, such an embodiment is illustrated, with conductive dots 8 placed on pads 10 of the substrate 4, while dielectric dots 6 are provided only on the die 2. As shown, dielectric dots may be cured before attachment (indicated by the rounded shape of the dielectric dots in FIG. 2b in contrast to the flat connected shape of the conductive dots 8); but they could as well be left uncured until the final curing step (not shown).

If desired, further combinations could be used, such as providing printed conductive dots 8 and uncured dielectric dots 6 on a die surface, while printing further dielectric dots 6 on the substrate surface and curing those before attachment. In this example, the dielectric cured dots on the substrate 4 would serve as spacer bumps, while the uncured dots on the die provide a conductive connection and a secure attachment after arranging the elements and subsequently curing all dots. Thus, e.g. the substrate printings may be cured as a whole, while the die printings are not cured until they are in connection with the substrate surface. The same combination of dots (or similar other combinations) can of course be used vice versa on die 2 and substrate 4.

Although dielectric bumps have been shown in the examples, these are not required for an electrical conducting attachment of the die. Still, they may be used e.g. as spacer elements for a uniform and even spacing of both surfaces, as mechanical protection, and also as attaching means if they are initially left uncured at least in part and then cured when in contact with both surfaces.

When placing two (or more) carrier members on top of each other for attachment, this may be done in a variety of ways. One or both of the carriers could be lifted up and placed on top of the remaining one. In that case, care should be taken that the uncured ink cannot smear or flow off its defined dot location. For example, the part having uncured ink dots may be left in place, while the other one with no printed structures or only cured printed structures may then be lifted up, turned as necessary (e.g. for a face-down attachment as in a flip-chip structure) and placed on top of the other part.

Various patterns of ink dots or bumps and further structures may be produced for connection elements and spacer/attaching elements. For example, elongated structures, circles or other structures may be printed. This may be achieved by placing several printing dots next to each other. Thus, in some embodiments different structures could be used for conductive connection bumps and dielectric spacer bumps to allow an adaptation of shape to the intended function. Terms like “dot” and “bump” as used in the above description of examples may be exchanged for such other structures without changing the basic concept.

Profile, shape and size of a dot or bump are determined (and thus may be controlled) by e.g. ink droplet volume, jetting velocity and jetting angle of the ink droplet from the aperture, ink material properties, the number of layers at one location, or the number of dots next to each other, which may also merge due to surface tension of the essentially liquid ink. Further parameters, such as parameters of the production environment (temperature, atmosphere, pressure, and many more) may also have influence on the bump appearance, as the person skilled in the art will understand.

Bump elements or dots (as well as any other structure) may be provided in various patterns. As shown in the examples of FIGS. 1 and 2, dielectric dots 6 may be placed in regular intervals on an interior area of the surface, while conductive dots 8 are then arranged around them, e.g. such that they will essentially be conform with landing pads 10 on the edge of a die when attached, as shown in FIGS. 1a and 2a. Dots could also be placed in specific locations, such as dielectric dots 6 alternating with conductive dots 8, to allow optimal distribution of support forces and pressure, to obtain good mechanical protection of electrical connections, and/or to facilitate printing and curing. This may in some embodiments be achieved by using a jet printing head having several apertures and ink reservoirs for different types of ink, or by using two printing heads at the same time. Alternatively, dots of different types may be printed subsequently, and the carrier to be printed may be moved to another printing head, or the further printing head may be moved towards the carrier.

The printed dots, especially the dielectric dots 6, may in some embodiments be cured partially after the printing step. In this way, dots and structures are stabilized to some extent without being fully cured. When substrate 4 and die 2 are placed on top of each other afterwards, with partially cured dots in between, these dots may also contribute to the attachment of surfaces when being completely cured. Thus, any combination of cured ink dots, partially cured dots, and uncured dots may for instance be used to attach a die, providing both an electrical connection and a secure attachment.

In the examples, a flip-chip type connection between a die and a substrate was illustrated. Nevertheless, the examples could easily be transferred to systems and procedures for connections between two or more stacked dies, or similar electrical connections between surfaces.

Although exemplary embodiments of the present invention have been described, these should not be construed to limit the scope of the appended claims. Those skilled in the art will understand that various modifications may be made to the described embodiments and that numerous other configurations or combinations of any of the embodiments are capable of achieving this same result. Moreover, to those skilled in the various arts, the invention itself will suggest solutions to other tasks and adaptations for other applications. It is the applicant's intention to cover by claims all such uses of the invention and those changes and modifications which could be made to the embodiments of the invention herein chosen for the purpose of disclosure without departing from the spirit and scope of the invention.

What is claimed is:

1. A method comprising
depositing of at least one dot of a conductive ink onto a first surface of a first carrier;
arranging said first carrier and a second carrier on top of each other, wherein said first surface of said first carrier and a first surface of said second carrier are facing each other; and
curing said at least one dot of conductive ink to achieve a conductive attachment between said carrier surfaces.

2. The method of claim 1, wherein said depositing of ink onto said surface comprises jet-printing of said ink.

3. The method of claim 2, wherein said jet-printing of ink is achieved by inducing mechanical pressure waves in an ink reservoir having an aperture.

4. The method of claim 3, wherein said pressure waves are generated by a piezo-electric element.

5. The method of claim 1, further comprising
depositing of at least one dot of a dielectric ink onto at least one of said first surface of said first carrier and said first surface of said second carrier.

6. The method of claim 5, further comprising
curing said at least one printed dielectric ink dot before arranging said carriers on top of each other.

7. The method of claim 1, wherein said curing is achieved by heating at least a part of said ink dots on said carrier surfaces.

8. The method of claim 5, wherein said curing is achieved by heating at least a part of said ink dots on said carrier surfaces.

9. The method of claim 1, further comprising
depositing at least one further layer of ink on top of deposited ink dots.

10. The method of claim 1, further comprising
depositing at least one further layer of ink on top of at least one of said cured ink dots, and curing said at least one further layer of ink.

11. The method of claim 1, wherein a plurality of ink dots is deposited, and wherein said volumes are deposited in a predetermined pattern.

12. The method of claim 3, wherein a plurality of said dots is deposited in a pattern which includes a number of said dielectric ink dots surrounded by a number of said conductive ink dots.

13. The method of claim 1, wherein said conductive ink dots are deposited on a metallized area of said carrier.

14. The method of claim 1, wherein at least one of said first and second carriers includes a semiconductor die.

15. The method of claim 1, wherein at least one of said first and second carriers includes a die substrate.

16. The method of claim 13, wherein said substrate comprises a polymer material.

17. The method of claim 13, wherein said substrate comprises a ceramic material.

18. The method of claim 13, wherein said substrate comprises a semiconductor material.

19. A device comprising
at least first and second carriers arranged on top of each other;
structures comprising at least one cured conductive ink dot between surfaces of said carriers; and
wherein said cured conductive ink dots are fixedly and directly connected to both of said carrier surfaces.

20. The device of claim 17, wherein said ink dots comprise nano-particles of a conductive material.

21. The device of claim 17, further comprising
structures comprising at least one cured dielectric ink dot between said surfaces of said carriers, wherein said cured dielectric ink dots are fixedly and directly connected to at least one of said carrier surfaces.

22. The device of claim 17 wherein at least one of said carriers is a semiconductor die.

23. The device of claim 17 wherein at least one of said carriers is a die substrate.

24. The device of claim 21 wherein said substrate comprises a polymer material.

25. The device of claim 21 wherein said substrate comprises a ceramic material.

26. The device of claim 21 wherein said substrate comprises a semiconductor material.
